(19) United States
(12) Patent Application Publication
(10) Pub. No.: US 2017/0099063 A1
(43) Pub. Date: Apr. 6, 2017

(54) METHOD AND APPARATUS FOR MEASURING SIGNAL-TO-QUANTIZATION-NOISE RATIO

(71) Applicant: Marvell World Trade Ltd., St. Michael (BB)

(72) Inventors: Vijay Ganwani, Pune (IN); Vijay Ahirwar, Bhopal (IN); Yui Lin, Palo Alto, CA (US); Sudhir Srinivasa, Campbell, CA (US); Hongyuan Zhang, Fremont, CA (US); Sridhar Narravula, Cupertino, CA (US)

(21) Appl. No.: 15/266,458

(22) Filed: Sep. 15, 2016

Related U.S. Application Data
(60) Provisional application No. 62/237,862, filed on Oct. 6, 2015.

(51) Int. Cl. H03M 3/00; H04L 27/26; H04B 1/10; H04L 7/033

(52) U.S. Cl. CPC H03M 3/378; H04L 7/0331; H04L 27/2636; H04B 1/1036; H03M 3/356; H04B 2001/1063

(57) ABSTRACT

Apparatus for determining a signal-to-quantization-noise ratio of a quantization circuit includes a signal generator that generates an input test signal for input to the quantization circuit, circuitry for isolating, from output of the quantization circuit, a signal representing quantization noise, and circuitry for determining a ratio of the output of the quantization circuit to the signal representing quantization noise. The signal generator generates an analog test tone having a frequency, and the circuitry for isolating includes a notch filter filtering that frequency. Alternatively, the circuitry for isolating includes circuitry for generating a digital test signal, and a digital subtractor for subtracting the digital test signal from the output of the quantization circuit. According to another alternative, the circuitry for isolating includes a transformation circuit whose outputs represent a peak of the output of the quantization circuit and a noise floor of the output of the quantization circuit.

### CROSS REFERENCE TO RELATED APPLICATION

This claims the benefit of copending, commonly-assigned U.S. Provisional Patent Application No. 62/237,862, filed Oct. 6, 2015, which is hereby incorporated by reference herein in its entirety.

### FIELD OF USE

Implementations of the subject matter of this disclosure generally pertain to a method, and apparatus, for measuring signal-to-quantization-noise ratio in a circuit in which a signal is quantized.

### BACKGROUND

The background description provided herein is for the purpose of generally presenting the context of the disclosure. Work of the inventor hereof, to the extent the work is described in this background section, as well as aspects of the description that may not otherwise qualify as prior art at the time of filing, are neither expressly nor impliedly admitted to be prior art against the present disclosure.

Any process that maps a larger number of input values to a smaller number of output values may be considered to be quantization. One common type of quantization is analog-to-digital conversion, where an essentially infinite number of input values of a continuous analog signal is converted to a finite number of discrete output values. However, there are other types of quantization. For example, rounding and truncation fall within the general definition of quantization.

Whenever any signal is quantized, there is a difference between the input signal and the output signal, and that difference may be referred to as “quantization error” or “quantization noise.” One measure of the degree of quantization noise is the signal-to-quantization-noise ratio (SQNR or SN_{q}R). For a particular circuit involving quantization, the SQNR may be measured either to allow for correction of the output, or to test whether the circuit is performing within desired specifications.

### SUMMARY

Apparatus according to implementations of the subject matter of this disclosure, for determining a signal-to-quantization-noise ratio of a quantization circuit, includes a signal generator that generates an input test signal for input to the quantization circuit, circuitry for isolating, from output of the quantization circuit, a signal representing quantization noise, and circuitry for determining a ratio of the output of the quantization circuit to the signal representing quantization noise.

According to one such implementation, the signal generator may generate an analog test tone having a frequency, and the circuitry for isolating comprises a notch filter that filters out the frequency. According to one variant, the notch filter is centered on the frequency. According to another variant, the notch filter is offset from the frequency and the notch filter has a notch bandwidth that is adjustable to encompass the frequency.

According to such an implementation, the circuitry for isolating further includes circuitry for compensating for DC offset in the output of the quantization circuit. The circuitry for compensating for DC offset may be downstream of the notch filter, or upstream of the notch filter.

According to another implementation of the subject matter of this disclosure, the circuitry for isolating may include circuitry for generating a digital test signal, and a digital subtractor for subtracting the digital test signal from the output of the quantization circuit.

In one such implementation, the circuitry for isolating may further include autocorrelation circuitry for determining phase of the output of the quantization circuit, and the circuitry for generating a digital test signal may include sinusoid generator circuitry, between the autocorrelation circuitry and the digital subtractor, for generating a sinusoidal signal phase-aligned to the output of the quantization circuit.

In another such implementation, the circuitry for generating a digital test signal comprises a phase-locked loop whose output is phase- and frequency-locked to the output of the quantization circuit.

According to yet another implementation of the subject matter of this disclosure, the circuitry for isolating may include a transformation circuit whose outputs represent a peak of the output of the quantization circuit and a noise floor of the output of the quantization circuit. The transformation circuit may be a Fast Fourier Transform circuit.

The signal generator, the circuitry for isolating and the circuitry for determining a ratio may all be on one integrated circuit device. Alternatively, the circuitry for isolating and the circuitry for determining a ratio may both be on one integrated circuit device, and the signal generator may be external to the one integrated circuit device.

In implementations of the subject matter of this disclosure, the circuitry for isolating may include circuitry for compensating for DC offset in the output of the quantization circuit.

A method according to implementations of the subject matter of this disclosure for determining a signal-to-quantization-noise ratio of a quantization circuit may include injecting a test signal into the quantization circuit, isolating, from output of the quantization circuit, a signal representing quantization noise, and determining a ratio of the output of the quantization circuit to the signal representing quantization noise.

According to one such implementation, the injecting may include injecting an analog test tone, having a tone frequency, into the quantization circuit, and the isolating may include filtering out the tone frequency from the output of the quantization circuit. The filtering out may include centering a notch filter on the tone frequency. Alternatively, the filtering out may include applying, to the output of the quantization circuit, a notch filter having a center frequency that is offset from the tone frequency, and adjusting bandwidth of the notch filter to encompass the tone frequency.

The isolating may further include compensating for DC offset in the output of the quantization circuit.

According to another implementation of a method according to the subject matter of this disclosure, the isolating may include determining, by autocorrelation, phase of the output of the quantization circuit, generating a digital test signal phase-aligned with the output of the quantization circuit, and digitally subtracting the digital test signal from the output of the quantization circuit.

According to another such implementation, the isolating may include generating a digital test signal that is phase- and frequency-locked to the output of the quantization circuit, and digitally subtracting the digital test signal from the output of the quantization circuit.

According to yet another implementation of a method according to the subject matter of this disclosure, the isolating may include applying a transformation whose outputs represent a peak of the output of the quantization circuit and a noise floor of the output of the quantization circuit. The transformation may be a Fast Fourier Transform.

### BRIEF DESCRIPTION OF THE DRAWINGS

Further features of the disclosure, its nature and various advantages, will be apparent upon consideration of the following detailed description, taken in conjunction with the accompanying drawings, in which like reference characters refer to like parts throughout, and in which:

FIG. 1 shows a first implementation of a circuit incorporating the subject matter of this disclosure;

FIG. 2 shows an alternate implementation of a circuit incorporating the subject matter of this disclosure;

FIG. 3 shows another implementation of a circuit incorporating the subject matter of this disclosure;

FIG. 4 shows still another implementation of a circuit incorporating the subject matter of this disclosure;

FIG. 5 shows yet another implementation of a circuit incorporating the subject matter of this disclosure; and

FIG. 6 is a flow diagram of an implementation of a method incorporating the subject matter of this disclosure.

### DETAILED DESCRIPTION

As noted above, quantization noise may arise in many different kinds of circuits or processes. In the description that follows, determination of quantization noise, in the form of the SQNR, will be described in the context of an analog-to-digital converter (ADC). Analog-to-digital converters are used in many types of signal processing circuits, including, but not limited to, digital transceivers such as those in BLUETOOTH® wireless circuits. However, it will be apparent to those of skill in the art that the method and apparatus described herein can be used to determine the SQNR for many types of quantization methods and circuits in many different signal processing applications.

In implementations described in this disclosure, the SQNR may be determined by injecting a test tone to the input of the quantization circuit (e.g., an analog-to-digital converter) and then isolating, from the quantized output, the quantized or digitized equivalent of the test tone and the quantization noise component. The SQNR can then be determined from those isolated components.

In some implementations described in this disclosure, the components may be isolated by subtracting out the digital equivalent of the test tone from the digitized signal. The remaining signal is the quantization noise. The SQNR can then be determined from the digitized signal, which represents the entire signal including the quantization noise, and the remaining signal, which represents only the quantization noise.

In another implementation described in this disclosure, a test tone is injected to the input of the quantization circuit and the digitized output is then subjected to a transformation function that inherently separates the components. For example, a Fast Fourier Transform function, by its nature, will break the digitized output signal into its various frequency components, each of which has a different amplitude. The SQNR may be calculated directly from the amplitudes of the peak and noise components.

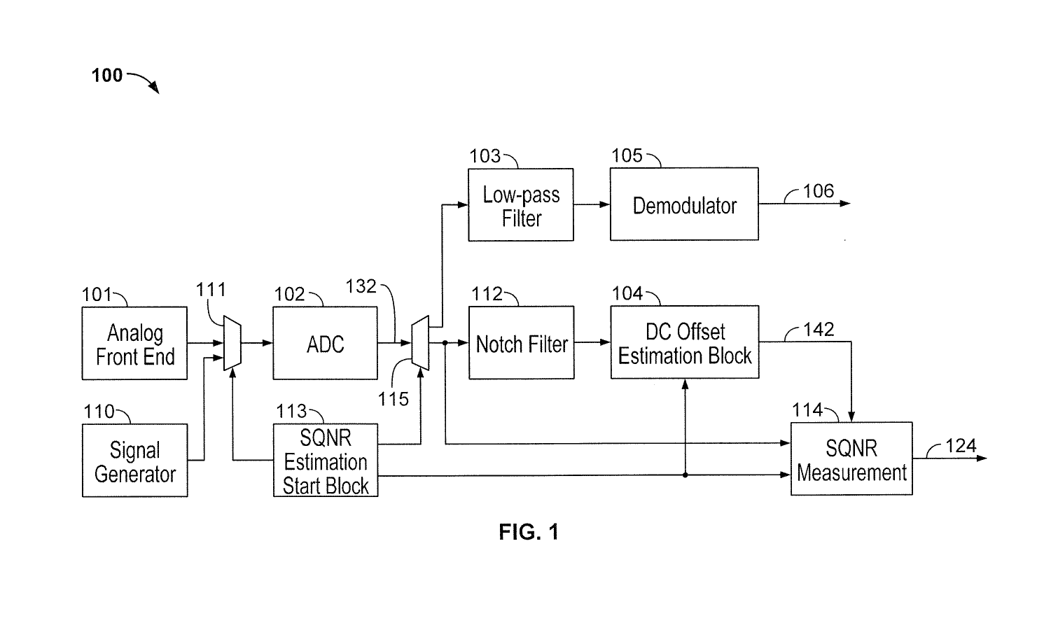

A first implementation of a circuit 100 incorporating the subject matter of this disclosure is shown in FIG. 1. As described above, circuit 100 may be part of a BLUETOOTH® wireless circuit, but alternatively could be part of any signal processing circuit. Circuit 100 as shown includes an analog front end 101. In a wireless technology, analog front end 101 may operate in the radiofrequency band. The output of analog front end 101 is input to analog-to-digital converter 102 or similar quantization circuitry. Circuit 100 may further include a low-pass filter 103 for adjacent channel rejection, a DC-offset estimation block 104 and a digital demodulator 105 which provides the output 106 of circuit 100.

In accordance with implementation of the subject matter of this disclosure, circuit 100 includes a signal generator 110 at the input of analog-to-digital converter 102. Signal generator 110 may be provided on the same integrated circuit as circuit 100, or may be provided externally and connected to circuit 100 (e.g., when an SQNR measurement is to be conducted). A multiplexer 111, for example, may be used to select between analog front end 101 and signal generator 110 as the input to analog-to-digital converter 102.

Circuit 100 for implementation of the subject matter of this disclosure also includes a digital notch filter 112, an SQNR estimation start block 113 and an SQNR measurement block 114.

As generally described above, in operation, a tone at a particular frequency is injected at the input of analog-to-digital converter 102 by signal generator 110. The amplitude of the tone is selected to be sufficient to cover the complete dynamic range of analog-to-digital converter 102. The signal at the output of analog-to-digital converter 102 includes a digitized or quantized version of the tone, along with the quantization noise and any DC offset that may be introduced by analog-to-digital converter 102.

During the tone injection, analog front end 101 is bypassed by selecting signal generator 110 using multiplexer 111. In addition, low-pass filter 103 and demodulator 105 are bypassed by multiplexer 115 in favor of notch filter 112 and DC-offset estimation block 104. Low-pass filter 103 is bypassed because it might tend to filter out contributions from the noise to be measured. Demodulator 105 is bypassed because there is no actual data signal to demodulate.

A signal is sent (e.g., by user input; not shown) to SQNR estimation start block 113 to indicate that SQNR estimation or measurement is to be performed. SQNR estimation start block 113 activates SQNR measurement block 114 as well as DC-offset estimation block 104, and also controls multiplexers 111, 115.

When circuit 100 is in SQNR estimation mode based on selections controlled by SQNR estimation start block 113 as a result of a user command, the injected tone from signal generator 110 is digitized by analog-to-digital converter 102. The output 132 of analog-to-digital converter 102 is a digitized or quantized version of the injected tone, including quantization noise.

Signal 132 is passed through digital notch filter 112, which removes the portion of signal 132 representing the digitized injected tone, leaving only the quantization noise and any remaining DC offset. Preferably, digital notch filter 112 is a static notch filter centered on the tone to be removed. DC-offset estimation block 104 removes any DC offset, leaving signal 142 which should include only the quantization noise.

The desired signal-to-quantization-noise ratio is the ratio of the peak power of signal 132 to that of signal 142, and is determined by SQNR measurement block 114 and output at 124. Signal 132 includes the quantization noise N_{q}, and SQNR measurement block 114 may determine the ratio between signal 132 and signal 142 (N_{q}), which ratio is actually (S+N_{q})/N_{q} rather than S/N_{q}. However, N_{q} is generally so small relative to S that the difference between (S+N_{q})/N_{q} and S/N_{q} is not significant. Alternatively, SQNR measurement block 114 may subtract signal 142 (N_{q}) from signal 132 before taking the ratio, so that the determined ratio is actually S/N_{q}.

SQNR estimation start block 113 can be designed to wait until various components have settled into a steady state before activating SQNR measurement block 114. For example, signal generator 110 and any automatic gain control (AGC) circuitry (not shown), may need time to settle down. In addition, depending on the characteristics of the notch filter, several sample periods may be required before the notch filter is filtering only the desired tone.

For example, the transfer function of one implementation of the notch filter may be represented as follows:

$$\begin{matrix}H ( z ) = ( \frac{( 1 - a ) - 2 ( 1 - a ) cos ω {z}^{- 1} + ( 1 - a ) {z}^{- 2}}{1 - 2 ( 1 - a ) cos ω {z}^{- 1} + ( 1 - 2 a ) {z}^{- 2}} ) , 0 < a < 1 \\ = \frac{( 1 - a ) + {bz}^{- 1} + ( 1 - a ) {z}^{- 2}}{1 + {bz}^{- 1} + ( 1 - 2 a ) {z}^{- 2}} , b = - 2 ( 1 - a ) cos ω\end{matrix}$$

where ω is the notch frequency and α is a parameter specifying the notch bandwidth (a smaller a results in a smaller bandwidth but a longer impulse response, while a larger α results in a larger bandwidth but a shorter impulse response). Because of the impulse response time of the notch filter, the first few samples of the filter output may be characterized by filter transients and should be discarded.

In addition, there may be an offset between the notch frequency, ω, and the tone frequency, which can affect the accuracy of the SQNR determination. This is an issue particularly when signal generator 110 is a separate device. If signal generator 110 is part of the same device as circuit 100, it generally will be of sufficient quality that the tone frequency can be known with certainty, and the notch frequency, ω, can be selected to match the tone frequency.

Whether or not signal generator 110 is part of the same device as circuit 100, one approach is to include as part of circuit 100 additional circuitry (not shown) that measures or estimates the tone frequency and adjusts the notch frequency, ω, accordingly. As noted above, this is more likely to be successful when signal generator 110 is part of the same device as circuit 100.

Another approach is to select a larger notch bandwidth when using a signal generator 110 that may not be of sufficient quality, and particularly when using an external signal generator 110. The notch bandwidth is determined by the parameter α. There is a balance in selecting the notch bandwidth represented by α. If the notch is too narrow, not all of the tone will be filtered out, but if the notch is too wide, too much of the quantization noise may be filtered out along with tone. Generally, α should be less than about 0.35, and may be as small as about 3.2×10⁻⁴.

The measured quantization noise may be observed to be periodic. The periodicity—i.e., the number of distinct quantization levels—depends on the tone frequency, ω. For example, for an analog-to-digital converter with an effective number of bits (ENOB) equal to 9, a tone frequency 107 of 1.5 MHz, 15.625 kHz or 1.7 MHz results in 32, 461 or 160 distinct quantization levels, respectively.

Although DC-offset estimation block 104 has been described as being used, along with notch filter 112, only during SQNR measurement, DC-offset estimation block 104 may optionally be used also during normal operation of circuit 100. In such a case, additional multiplexing or switching elements may be provided (not shown) to allow DC-offset estimation block 104 to be connected between notch filter 112 and SQNR measurement block 114 during SQNR measurement, and to be connected in line with low-pass filter 103 and demodulator 105 during normal operation.

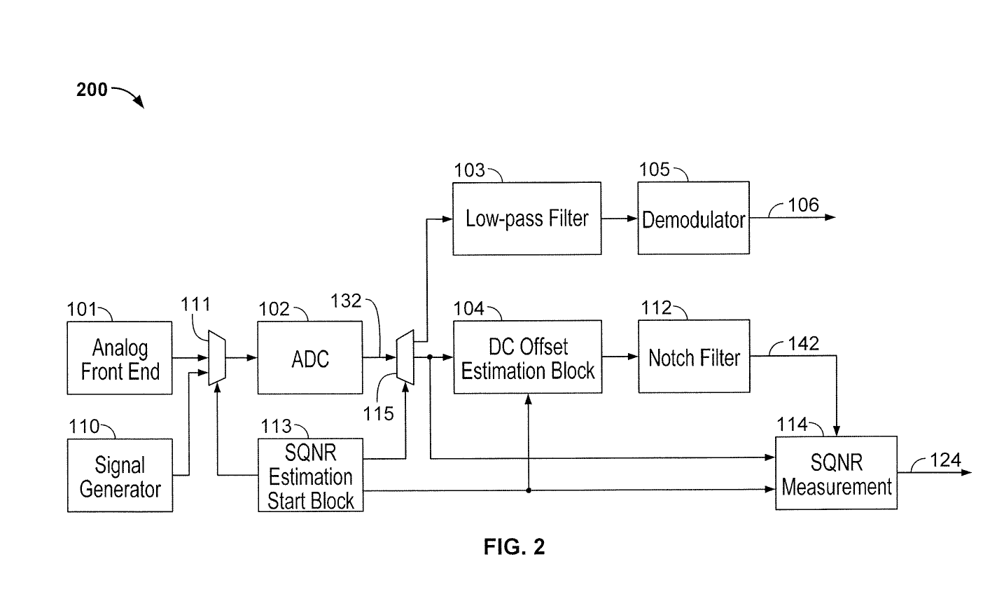

An alternative circuit 200, shown in FIG. 2, is similar to circuit 100 except that during SQNR measurement, DC-offset estimation block 104 precedes digital notch filter 112, cancelling any DC offset from signal 132 before the injected tone is filtered out. Circuit 200 otherwise operates like circuit 100. As noted in connection with circuit 100, additional multiplexing or switching elements (not shown) may optionally be provided to allow DC-offset estimation block 104 to be connected in line with notch filter 112 and SQNR measurement block 114 during SQNR measurement, and to be connected in line with low-pass filter 103 and demodulator 105 during normal operation.

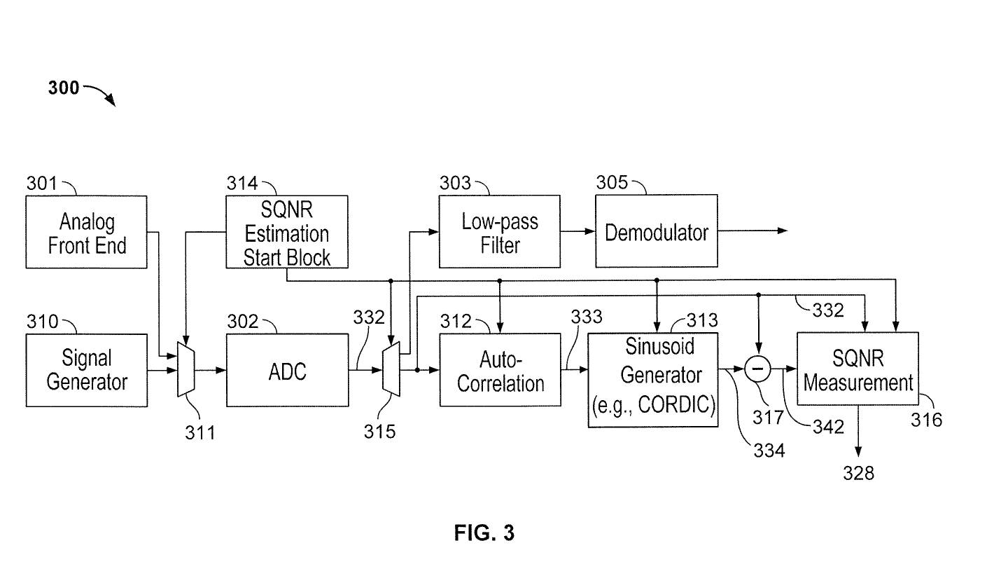

Another implementation of a circuit 300 incorporating the subject matter of this disclosure is shown in FIG. 3. Whereas in circuit 100 or circuit 200, a representation of the digitized tone is filtered out of the digitized tone signal using a notch filter to leave the quantization noise, in circuit 300, autocorrelation is used to create a high-resolution digitized tone which is subtracted from the quantized test tone to leave the quantization noise.

Specifically, circuit 300 includes a signal generator 310 on the same integrated circuit device as circuit 300. Signal generator 310 may be an analog signal generator. A multiplexer 311, for example, may be used to select between analog front end 301 and signal generator 310 as the input to analog-to-digital converter 302.

Circuit 300 for implementation of the subject matter of this disclosure also includes an autocorrelation block 312, a sinusoid generator 313 (which may operate, e.g., according to the CORDIC method), an SQNR estimation start block 314 and an SQNR measurement block 316.

In operation, a tone at a particular frequency is injected at the input of analog-to-digital converter 302 by signal generator 310. The amplitude of the tone is selected to be sufficient to cover the complete dynamic range of analog-to-digital converter 302. The quantized tone signal at the output of analog-to-digital converter 302 includes a quantized version of the tone, along with the quantization noise. As in the case of circuit 100, a DC-offset estimation block (not shown) such as DC-offset estimation block 104 may be provided to remove any DC offset from the output of analog-to-digital converter 302.

During the tone injection, analog front end 301 is bypassed by selecting signal generator 310 using multiplexer 311. In addition, low-pass filter 303 and demodulator 305 are bypassed by multiplexer 315. Low-pass filter 303 is bypassed because it might tend to filter out contributions from the noise to be measured. Demodulator 305 is bypassed because there is no actual data signal to demodulate.

A signal is sent (e.g., by user input; not shown) to SQNR estimation start block 314 to indicate that SQNR estimation or measurement is to be performed. SQNR estimation start block 314 activates SQNR measurement block 316 as well as autocorrelation block 312 and sinusoid generator 313, and also controls multiplexers 311, 315.

When circuit 300 is in SQNR estimation mode based on selections controlled by SQNR estimation start block 314 as a result of a user command, the injected tone from signal generator 310 is quantized by analog-to-digital converter 302. The output 332 of analog-to-digital converter 302 is a quantized version of the injected tone, including quantization noise.

Signal 332 is passed through autocorrelation block 312, to determine the phase of signal 332 using autocorrelation. Once the phase has been determined, the phase is communicated at 333 to sinusoid generator 313. The frequency of signal 332 also may be passed at 333, or sinusoid generator 313 can be constructed to generate the same frequency as signal generator 310. Using the phase information 333, sinusoid generator 313 can generate a signal 334 that is properly aligned with signal 332 so that signal 334 can be subtracted from signal 332 by digital subtractor 317 to provide the quantization error represented by signal 342.

The desired signal-to-quantization-noise ratio is the ratio of the peak power of quantized signal 332 to that of signal 342, and is determined by SQNR measurement block 316 and output at 328. As in the case of circuit 100, signal 332 includes the quantization noise N_{q}, and SQNR measurement block 316 may determine the ratio between signal 332 and signal 342 (N_{q}), which ratio is actually (S+N_{q})/N_{q} rather than S/N_{q}. However, N_{q} is generally so small relative to S that the difference between (S+N_{q})/N_{q} and S/N_{q} is not significant. Alternatively, SQNR measurement block 316 may subtract signal 342 (N_{q}) from signal 332 before taking the ratio, so that the determined ratio is actually S/N_{q}.

SQNR estimation start block 314 can be designed to wait until various components have settled into a steady state before activating SQNR measurement block 316.

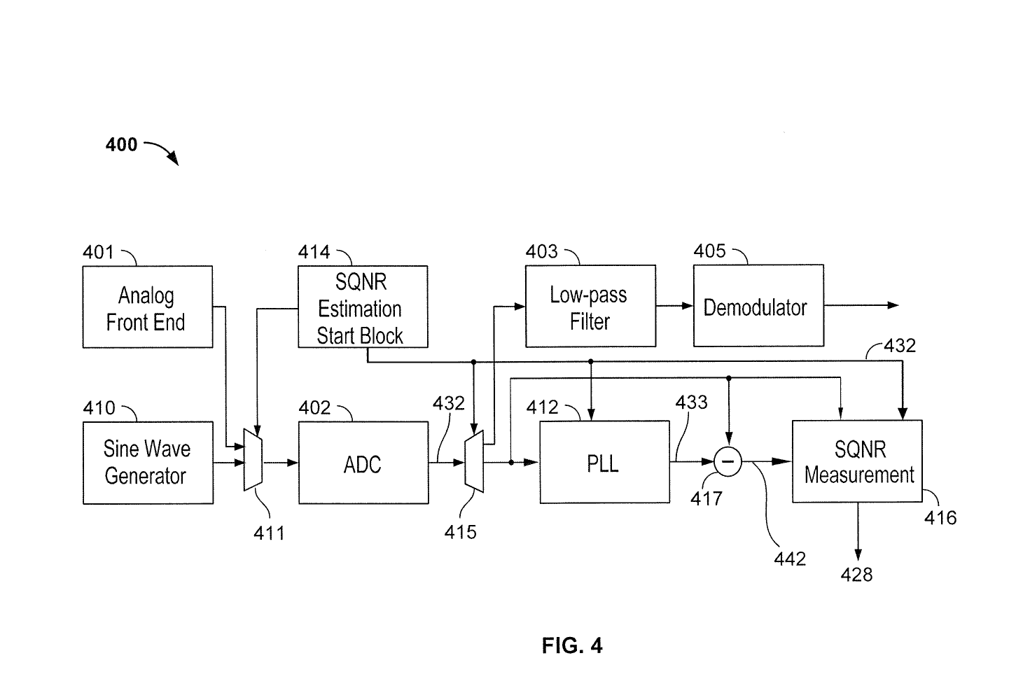

Another implementation of a circuit 400 incorporating the subject matter of this disclosure is shown in FIG. 4. As in circuit 300, in circuit 400, a high-resolution digitized tone is subtracted from the quantized test tone to leave the quantization noise. In this implementation, the high-resolution digitized tone is created by a phase-locked loop (PLL) that locks to the quantized test tone.

Specifically, circuit 400 includes a sine wave generator 410 which may be on the same integrated circuit device as circuit 400, or may be provided externally and connected to circuit 400 (e.g., when an SQNR measurement is to be conducted). A multiplexer 411, for example, may be used to select between analog front end 401 and signal generator 410 as the input to analog-to-digital converter 402.

Circuit 400 for implementation of the subject matter of this disclosure also includes a phase-locked loop (PLL) 412, an SQNR estimation start block 414 and an SQNR measurement block 416.

In operation, a test signal at a particular frequency is injected at the input of analog-to-digital converter 402 by sine wave generator 410. The amplitude of the test signal is selected to be sufficient to cover the complete dynamic range of analog-to-digital converter 402. A quantized version of the input test signal at the output of analog-to-digital converter 402 is a quantized version of the test signal, along with the quantization noise. As in the case of circuit 100, a DC-offset estimation block (not shown) such as DC-offset estimation block 104 may be provided to remove any DC offset from the output of analog-to-digital converter 402.

During the test signal injection, analog front end 401 is bypassed by selecting signal generator 410 using multiplexer 411. In addition, low-pass filter 403 and demodulator 405 are bypassed by multiplexer 415. Low-pass filter 403 is bypassed because it might tend to filter out contributions from the noise to be measured. Demodulator 405 is bypassed because there is no actual data signal to demodulate.

A signal is sent (e.g., by user input; not shown) to SQNR estimation start block 414 to indicate that SQNR estimation or measurement is to be performed. SQNR estimation start block 414 activates SQNR measurement block 416 as well as PLL 412, and also controls multiplexers 411, 415.

When circuit 400 is in SQNR estimation mode based on selections controlled by SQNR estimation start block 414 as a result of a user command, the injected test signal from sine wave generator 410 is quantized by analog-to-digital converter 402. The output 432 of analog-to-digital converter 402 is a quantized version of the injected test signal, including quantization noise.

PLL 412 locks onto signal 432, generating an output signal 433 at the same frequency and phase as signal 432, but at higher resolution. For example, analog-to-digital converter 402 may provide signal 432 at a resolution of 9-10 bits, while PLL 412 may provide signal 433 at a resolution of 20-32 bits. Because signal 433 is phase-locked to signal 432, signal 433 is properly aligned with signal 432 and can be subtracted from signal 432 by digital subtractor 417 to provide the quantization error represented by signal 442.

The desired signal-to-quantization-noise ratio is the ratio of the peak power of quantized signal 432 to that of signal 442, and is determined by SQNR measurement block 416 and output at 428. As in the case of circuit 100, signal 432 includes the quantization noise N_{q}, and SQNR measurement block 416 may determine the ratio between signal 432 and signal 442 (N_{q}), which ratio is actually (S+N_{q})/N_{q} rather than S/N_{q}. However, N_{q} is generally so small relative to S that the difference between (S+N_{q})/N_{q} and S/N_{q} is not significant. Alternatively, SQNR measurement block 416 may subtract signal 442 (N_{q}) from signal 432 before taking the ratio, so that the determined ratio is actually S/N_{q}.

SQNR estimation start block 414 can be designed to wait until various components have settled into a steady state before activating SQNR measurement block 416.

The implementations of circuits 100 and 200, on the one hand, and circuits 300 and 400, on the other hand, are similar in that the quantization noise is isolated from the signal power by subtracting one representation of the injected tone from another representation of the injected tone (by filtering in circuits 100 and 200, and by subtraction in circuits 300 and 400). The ratio of the signal power of the digitized tone to the signal power of the quantization noise can then be determined.

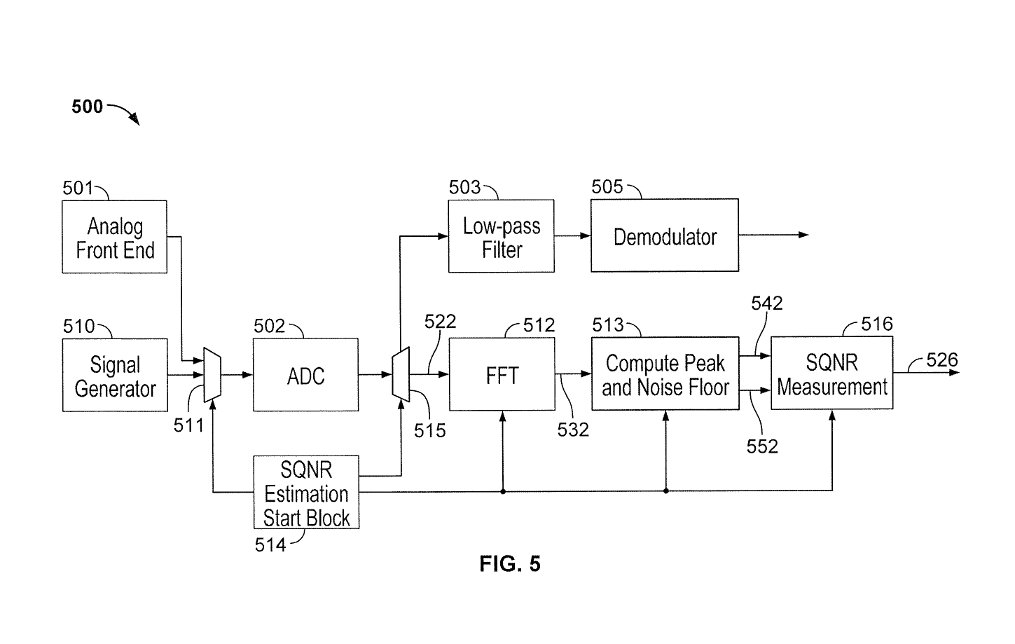

In another implementation of a circuit 500 incorporating the subject matter of this disclosure, which is shown in FIG. 5, the peak power of the digitized tone and the quantization noise may be isolated directly by transforming the digitized tone—e.g., using a Fast Fourier Transform.

Circuit 500 includes a signal generator 510 at the input of analog-to-digital converter 502. Signal generator 510 may be provided on the same integrated circuit as circuit 500, or may be provided externally and connected to circuit 500 (e.g., when SQNR measurement is to be conducted). A multiplexer 511, for example, may be used to select between analog front end 501 and signal generator 510 as the input to analog-to-digital converter 502.

Circuit 500 for implementation of the subject matter of this disclosure also includes a Fast Fourier Transform block 512, a peak-and-noise-floor computation block 513, an SQNR estimation start block 514 and an SQNR measurement block 516.

In operation, a tone at a particular frequency is injected at the input of analog-to-digital converter 502 by signal generator 510. The amplitude of the tone is selected to be sufficient to cover the complete dynamic range of analog-to-digital converter 502. The signal at the output of analog-to-digital converter 502 includes a digitized or quantized version of the tone, along with the quantization noise and any DC offset. As in the case of circuit 100, a DC-offset estimation block (not shown) such as DC-offset estimation block 104 may be provided to remove any DC offset from the output of analog-to-digital converter 402.

During the tone injection, analog front end 501 is bypassed by selecting signal generator 510 using multiplexer 511. In addition, low-pass filter 503 and demodulator 505 are bypassed by multiplexer 515. Low-pass filter 503 is bypassed because it might tend to filter out contributions from the noise to be measured. Demodulator 505 is bypassed because there is no actual data signal to demodulate.

A signal is sent (e.g., by user input; not shown) to SQNR estimation start block 514 to indicate that SQNR estimation or measurement is to be performed. SQNR estimation start block 514 activates SQNR measurement block 516 as well as Fast Fourier Transform block 512 and peak-and-noise-floor computation block 513, and also controls multiplexers 511, 515.

When circuit 500 is in SQNR estimation mode based on selections controlled by SQNR estimation start block 514 as a result of a user command, the injected tone from signal generator 510 is digitized by analog-to-digital converter 502. The output 522 of analog-to-digital converter 502 is a digitized or quantized version of the injected tone, including quantization noise.

Signal 522 is passed through Fast Fourier Transform block 512 and peak-and-noise-floor computation block 513. Peak-and-noise-floor computation block 513 determines the peak power 542 and the noise floor 552 of Fourier-transformed signal 532, and the desired signal-to-quantization-noise ratio is the ratio of those values, which may be computed by SQNR measurement block 516 and output at 526.

SQNR estimation start block 514 can be designed to wait until various components have settled into a steady state before activating SQNR measurement block 516.

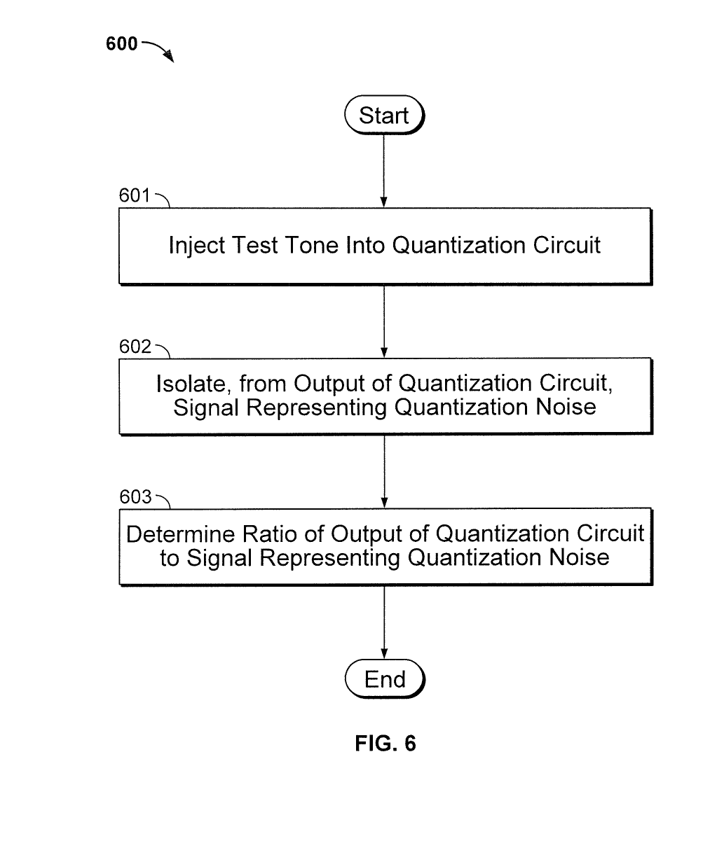

FIG. 6 is a flow diagram of an implementation of a method 600 incorporating the subject matter of this disclosure.

Method 600 begins at 601 where a test tone is injected into a quantization circuit. At 602, a signal representing quantization noise is isolated from output of the quantization circuit. At 603, a ratio of the output of the quantization circuit to the signal representing quantization noise is determined, and method 600 ends.

Thus it seen that apparatus and methods for determining the signal-to-quantization-noise ratio for a quantization circuit, by injecting a test tone to the input of the quantization circuit and then isolating, from the quantized output, the quantized or digitized equivalent of the test tone and the quantization noise component, from which the signal-to-quantization-noise ratio can be determined, have been provided.

It will be understood that the foregoing is only illustrative of the principles of the invention, and that the invention can be practiced by other than the described embodiments, which are presented for purposes of illustration and not of limitation, and the present invention is limited only by the claims which follow.

1. Apparatus for determining a signal-to-quantization-noise ratio of a quantization circuit, the apparatus comprising:
a signal generator that generates an input test signal for input to the quantization circuit;
circuitry for isolating, from output of the quantization circuit, a signal representing quantization noise; and
circuitry for determining a ratio of the output of the quantization circuit to the signal representing quantization noise.

2. The apparatus of claim 1, wherein:
the signal generator generates an analog test tone having a frequency; and
the circuitry for isolating comprises a notch filter that filters out the frequency.

3. The apparatus of claim 2 wherein the notch filter is centered on the frequency.

4. The apparatus of claim 2 wherein:
the notch filter is offset from the frequency; and
the notch filter has a notch bandwidth that is adjustable to encompass the frequency.

5. The apparatus of claim 2 wherein the circuitry for isolating further comprises circuitry for compensating for DC offset in the output of the quantization circuit.

6. The apparatus of claim 5 wherein the circuitry for compensating for DC offset is downstream of the notch filter.

7. The apparatus of claim 5 wherein the circuitry for compensating for DC offset is upstream of the notch filter.

8. The apparatus of claim 1, wherein the circuitry for isolating further comprises:
circuitry for generating a digital test signal; and
a digital subtractor for subtracting the digital test signal from the output of the quantization circuit.

9. The apparatus of claim 8 wherein:
the circuitry for isolating further comprises autocorrelation circuitry for determining phase of the output of the quantization circuit; and
the circuitry for generating a digital test signal comprises sinusoid generator circuitry, between the autocorrelation circuitry and the digital subtractor, for generating a sinusoidal signal phase-aligned to the output of the quantization circuit.

10. The apparatus of claim 8 wherein the circuitry for generating a digital test signal comprises a phase-locked loop whose output is phase- and frequency-locked to the output of the quantization circuit.

11. The apparatus of claim 1, wherein the circuitry for isolating comprises a transformation circuit whose outputs represent a peak of the output of the quantization circuit and a noise floor of the output of the quantization circuit.

12. The apparatus of claim 11 wherein the transformation circuit implements a Fast Fourier Transform.

13. The apparatus of claim 1, wherein the signal generator, the circuitry for isolating and the circuitry for determining a ratio are all on one integrated circuit device.

14. The apparatus of claim 1, wherein:
the circuitry for isolating and the circuitry for determining a ratio are both on one integrated circuit device; and
the signal generator is external to the one integrated circuit device.

15. The apparatus of claim 1 wherein the circuitry for isolating further comprises circuitry for compensating for DC offset in the output of the quantization circuit.

16. A method for determining a signal-to-quantization-noise ratio of a quantization circuit, the method comprising:
injecting a test signal into the quantization circuit;
isolating, from output of the quantization circuit, a signal representing quantization noise; and
determining a ratio of the output of the quantization circuit to the signal representing quantization noise.

17. The method of claim 16, wherein:
the injecting comprises injecting an analog test tone, having a tone frequency, into the quantization circuit; and
the isolating comprises filtering out the tone frequency from the output of the quantization circuit.

18. The method of claim 17, wherein the filtering out comprises centering a notch filter on the tone frequency.

19. The method of claim 17, wherein the filtering comprises:
applying, to the output of the quantization circuit, a notch filter having a center frequency that is offset from the tone frequency; and
adjusting bandwidth of the notch filter to encompass the tone frequency.

20. The method of claim 17 wherein the isolating further comprises compensating for DC offset in the output of the quantization circuit.

21. (canceled)

21-23. (canceled)

24. The method of claim 16, wherein the isolating comprises:
determining, by autocorrelation, phase of the output of the quantization circuit,
generating a digital test signal phase-aligned with the output of the quantization circuit; and
digitally subtracting the digital test signal from the output of the quantization circuit.

25. The method of claim 16, wherein the isolating comprises:
generating a digital test signal that is phase- and frequency-locked to the output of the quantization circuit; and
digitally subtracting the digital test signal from the output of the quantization circuit.

26. The method of claim 16, wherein the isolating comprises applying a transformation whose outputs represent a peak of the output of the quantization circuit and a noise floor of the output of the quantization circuit.

27. The method of claim 26 wherein the applying comprises applying a Fast Fourier Transform.
